(19) United States
(12) Patent Application Publication
(10) Pub. No.: US 2024/0036072 A1
(43) Pub. Date: Feb. 1, 2024

(54) TEST PROBES AND TEST SOCKET FOR USE WITH THE SAME

(71) Applicant: Hirose Electric Co., Ltd., Yokohama (JP)

(72) Inventor: Tatsuya ARAI, Yokohama (JP)

(21) Appl. No.: 18/212,927

(22) Filed: Jun. 22, 2023

(30) Foreign Application Priority Data
Jun. 23, 2022 (JP) 2022-100877

(51) Int. Cl. G01R 1/067

(52) U.S. Cl. CPC G01R 1/06733; G01R 1/06722

(57) ABSTRACT

[Problem] To provide test probes that are smaller and have, or are capable of having, shielding capability in a simple manner, as well as a test socket for use with said test probes.

[Means of Solution] A test probe comprising a hollow outer casing made of an electrically conductive material, a resilient member installed within the outer casing in a manner permitting contraction and expansion in an axial direction, and contact members installed within the outer casing in a state of being constantly biased by the resilient member while partially protruding outside of the outer casing, wherein the probe is configured such that the outer casing includes a cylindrical main body portion extending in the axial direction and a shielding portion provided along the axial direction as a protrusion in a radial direction of the main body portion in part of the peripheral surface of the main body portion, or alternatively, such that the outer casing includes a cylindrical main body portion extending in the axial direction and a recessed portion provided along the axial direction as an indentation in a radial direction of the main body portion in part of the peripheral surface of the main body portion, and an end of the shielding portion and/or an end of a shielding member of another test probe to be coupled can be installed in the recessed portion.

### TECHNICAL FIELD

The present invention relates to test probes, and, more specifically, to test probes specially adapted for use as ground probes that have, or are capable of having, shielding capability, as well as to a test socket for use with the test probes.

### BACKGROUND ART

Test probes, which are used for electrical testing of array-based electronic devices such as IC chips produced by placing a plurality of solder balls, pads, leads, and the like on a package, for example, are employed as power supply probes and signal probes, and are also employed as ground probes and the like.

An exemplary mode of use, in which test probes are employed as ground probes, has been disclosed in Patent Document 1 (Japanese Patent Publication No. 6,475,479). It should be noted that reference numerals used in the discussion below follow the reference numerals of Patent Document 1.

Patent Document 1 relates to a test unit 30 constituting a high-frequency type socket, wherein the test unit 30 comprises a metal block (pin block) 50 having multiple through-openings 51 formed therein, ground contact probes 40A inserted and placed within these through-openings 51 in the metal block, power supply contact probes 40B, and high-frequency signal contact probes 40C, ground bushings 60 disposed around the periphery of the ground contact probes 40A, a plastic plate that serves as an insulator plate (pin plate) 70, and insulator rings 75 that serve as insulating members.

The ground contact probes 40A, along with the power supply contact probes 40B and high-frequency signal contact probes 40C, are inserted and placed within the metal block 50, and, in the same manner as the power supply contact probes 40B and high-frequency signal contact probes 40C, are also insulated from the metal block 50 by the insulator rings 75 and the plastic plate that serves as an insulator plate. In this state, it is therefore impossible to enable the ground contact probes 40A to exhibit grounding capability.

In order to enable the ground contact probes 40A to exhibit intrinsic capabilities, Patent Document 1 provides ground contact probes 40A in which ground bushings 60 made of a conductive metal are placed around the periphery of the ground contact probes 40A, thereby electrically connecting the metal block 50 to the ground contact probes 40A and thus causing the metal block 50 to serve as a shielding portion.

### PRIOR ART DOCUMENTS

### Patent Documents

### [Patent Document 1]

Japanese Patent Publication No. 6,475,479

### SUMMARY OF THE INVENTION

### Problems to be Solved by the Invention

As can be seen from the description of Patent Document 1, a fixed concept postulating that test probes should be cylindrical in shape has existed in the past among those skilled in the art. This fixed concept is believed to be the reason why Patent Document 1 adopted a configuration in which the ground bushings and the metal block were utilized to impart grounding capability to the contact probes in spite of the increased size and complexity of the apparatus, as well as the restrictions imposed on the freedom of design.

The present invention revolutionizes this fixed concept held by those skilled in the art and makes changes to the shape of the test probes themselves, which have been perceived to be necessarily cylindrical, thereby providing test probes that have, or are capable of having, shielding capability in a simple manner without increasing the size of the apparatus, as well as a test socket for use with the test probes.

### Means for Solving the Problems

In order to solve the above-mentioned problems, a test probe according to one aspect of the present invention comprises a hollow outer casing made of an electrically conductive material, a resilient member installed within the outer casing in a manner permitting contraction and expansion in an axial direction, and contact members installed within the outer casing in a state of being constantly biased by the resilient member while partially protruding outside of the outer casing, and
is configured such that the outer casing includes a cylindrical main body portion extending in the axial direction and a shielding portion provided along the axial direction as a protrusion in a radial direction of the main body portion in part of the peripheral surface of the main body portion, or alternatively,
such that the outer casing includes a cylindrical main body portion extending in the axial direction and a recessed portion provided along the axial direction as an indentation in a radial direction of the main body portion in part of the peripheral surface of the main body portion, and an end of the shielding portion and/or an end of a shielding member of another test probe to be coupled can be installed in the recessed portion.

In accordance with the test probe of this aspect, a test probe specially adapted for use as a ground probe, to which shielding capability is imparted or can be imparted, can be provided by making changes to the shape of the test probe itself

### Effects of the Invention

In accordance with the present invention, there are provided test probes having, or capable of having, shielding capability, as well as a test socket for use with said test probes.

### BRIEF DESCRIPTION OF THE DRAWINGS

FIG. 1 A perspective view of a typical conventional test probe, and a perspective view illustrating its internal structure.

FIG. 2 A schematic perspective view of a test probe according to a first exemplary embodiment of the present invention.

FIG. 3 A perspective view illustrating a variation of the test probe of FIG. 1.

FIG. 4 A perspective view illustrating an example of the placement of test probes in a test socket.

FIG. 5 A plan view illustrating an example of the placement of test probes.

FIG. 6 A plan view illustrating an example of the placement of test probes corresponding to FIG. 5.

FIG. 7 A perspective view illustrating a variation of the test probe of FIG. 1.

FIG. 8 A plan view illustrating an example of the placement of test probes.

FIG. 9 A perspective view illustrating an exemplary aspect involving test probe coupling.

FIG. 10 A perspective view illustrating an exemplary aspect involving test probe coupling.

FIG. 11 A schematic perspective view of a test probe according to a second exemplary embodiment of the present invention.

FIG. 12 A perspective view illustrating a variation of the test probe of FIG. 11.

FIG. 13 A perspective view illustrating an aspect involving coupling a test probe provided with both recessed portions and a shielding portion and a test probe having only recessed portions.

FIG. 14 A plan view of FIG. 13.

FIG. 15 A perspective view illustrating an exemplary aspect involving coupling the test probes illustrated in FIG. 13.

FIG. 16 A plan view illustrating an aspect involving coupling test probes having only recessed portions.

FIG. 17 A plan view illustrating another aspect involving coupling test probes having only recessed portions.

FIG. 18 A schematic perspective view of a test socket according to an exemplary embodiment of the present invention.

FIG. 19 A perspective partial cut-away view illustrating an arrangement of the test probes accommodated in the lower housing.

FIG. 20 A schematic plan view of FIG. 19.

FIG. 21 A plan view illustrating the placement of retaining members and through-holes before the installation of test probes.

FIG. 22 A perspective cross-sectional view taken along line A-A in FIG. 21.

### MODE FOR CARRYING OUT THE INVENTION

Exemplary embodiments for practicing the present invention will be described in detail below with reference to drawings. However, the materials, shapes, relative positions of components, and the like described in the embodiments below, except for matters essential to solving the problems of the present invention, are discretionary and can be modified depending on the configuration or various conditions of the apparatus to which the present invention is applied. In addition, unless expressly stated otherwise, the scope of the present invention is not limited to the embodiments specifically described below.

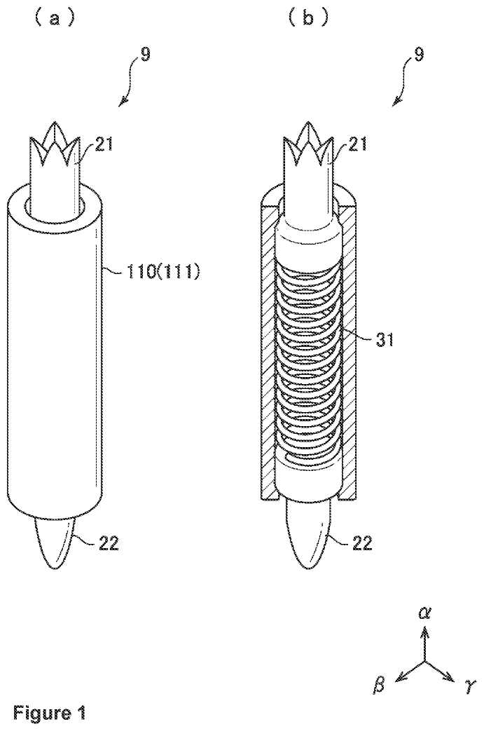

FIG. 1 shows a perspective view of the typical conventional test probe 9 disclosed in Patent Document 1, etc., which is a test probe having no shielding capability (FIG. 1(a)), and a perspective view of its internal structure (FIG. 1(b)). The test probe 9 comprises a hollow outer casing 110 formed in a cylindrical configuration, a resilient member 31 installed within the outer casing 110, and contact members 21, 22 installed within the outer casing 110 while partially protruding outside of the outer casing 110.

The outer casing 110, which is made of an electrically conductive material, is formed, for example, by stamping and bending a sheet of metal.

The resilient member 31 which is, for example, a coil spring such as the one shown in FIG. 1, is installed within the outer casing 110 in a manner permitting contraction and expansion in the axial direction “α”. Although it does not necessarily have to be formed from an electrically conductive material, forming the resilient member 31 from an electrically conductive material can also improve electrical connections between the contact member 21 and contact member 22, as well as between these contact members 21, 22 and the outer casing 110.

The contact members 21, 22, which are also made of an electrically conductive material in the same manner as the outer casing 110, are formed, for example, by machining blocks of metal. However, instead of machining, or in combination with machining, they may also be formed by stamping and bending a sheet of metal. The contact members 21, 22, which are members that serve as so-called plungers, are constantly biased by the resilient member 31 and are placed in conductive communication with the outer casing 110 and, furthermore, if the resilient member 31 is formed from an electrically conductive material, are in communication with that resilient member 31.

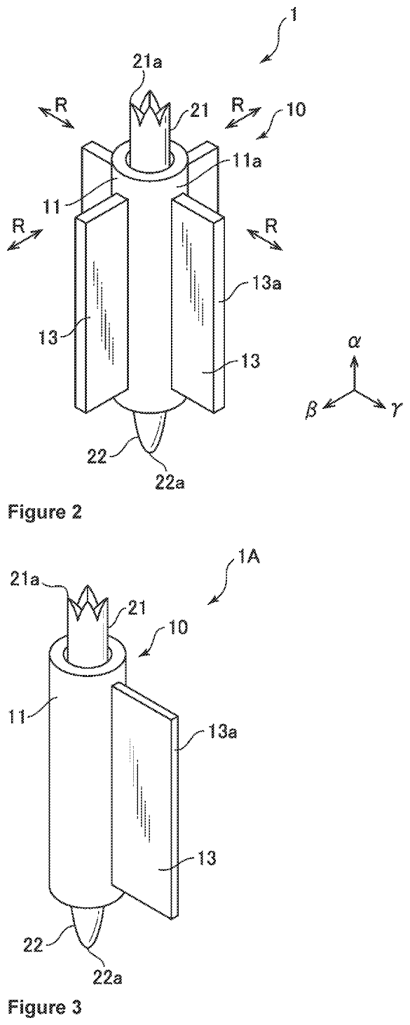

FIG. 2 shows a schematic perspective view of a test probe 1 according to a first exemplary embodiment of the present invention. The test probe 1 has an outer casing that is different from that of the test probe 9 illustrated in FIG. 1. More specifically, while the outer casing 110 of the test probe 9 is a main body portion 111 of a purely cylindrical shape extending in the axial direction “α”, the outer casing 10 of the test probe 1 includes shielding portions 13 in addition to a main body portion 11. It should be noted that, other than the outer casing, there is no substantial difference between test probe 1 and test probe 9 in terms of elements, such as the resilient member 31 and the contact members 21, 22.

The shielding portions 13, which are constituted by electrically conductive members, can be formed integrally with the main body portion 11, for example, by stamping and bending a sheet of metal, or by machining blocks of metal. However, they do not necessarily have to be formed integrally with the main body portion 11 and, after having been formed separately from the main body portion 11, may be secured to the main body portion 11 by welding or the like.

Each shielding portion 13 is provided as a protrusion in the radial direction “R” of the main body portion 11 in a part of the peripheral surface 11a of the main body portion 11. Protruding in the radial direction may impart a capability to shield adjacent test probes.

In addition, each shielding portion 13 is provided over a predetermined length along the axial direction “α”. This length can be determined freely by considering the size and shielding effects of the apparatus.

The number of the shielding portions 13 is not particularly limited. Although a total of four shielding portions 13 are provided in test probe 1, only one shielding portion may be provided, for example, as is the case with the test probe 1A illustrated in FIG. 3.

If a plurality of shielding portions 13 are provided, as shown in FIG. 2, these shielding portions 13 may be placed in a radial configuration and in an equidistantly spaced relationship with respect to one another in the “β-γ” plane. Placement in a radial configuration makes it possible to shield more test probes 1 and equidistant spacing allows for the test probe placement design to be simplified and made more efficient. However, the placement does not necessarily have to be radial or equidistantly spaced. The method of placement can be modified as appropriate depending on the mode of use.

In the “β-γ” plane, each shielding portion 13 may have a linear shape extending in a substantially even width. For example, as shown in FIG. 2, it may be shaped as a narrow strip, in which case the shielding portion 13, as a whole, is formed as a thin plate-like body. The shape of the plate-like body is not particularly limited. For example, if a rectangular shape is used, as shown in FIG. 2, the placement design can be simplified and made more efficient. However, its shape can be modified as appropriate depending on the mode of use.

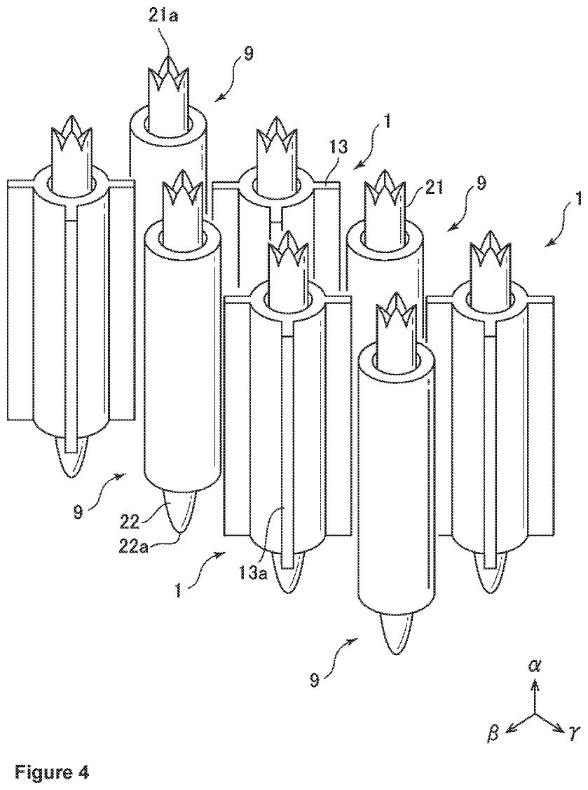

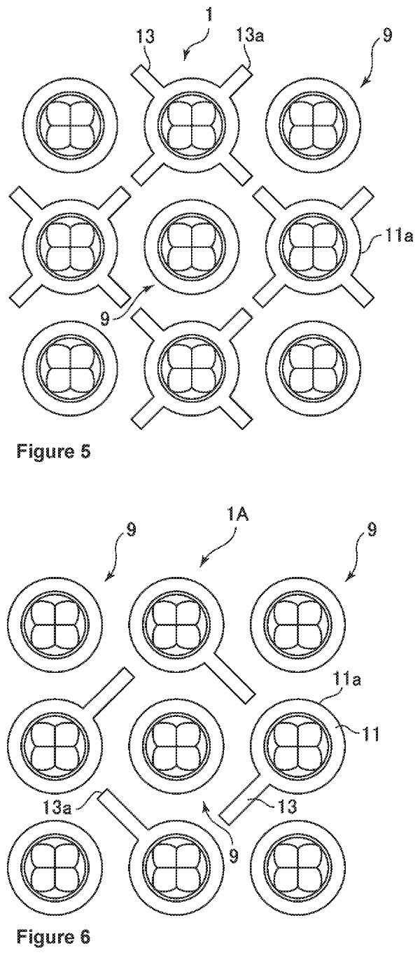

FIG. 4 is a perspective view illustrating an example of the placement of test probes 1 in a test socket (omitted here for simplicity). Further, FIG. 5 is a plan view illustrating another example of placement of test probes 1, and, furthermore, FIG. 6 is a plan view illustrating an example of the placement of test probes 1A corresponding to FIG. 5.

The test probes 1, 1A are placed in the test socket together with, for example, typical conventional test probes 9. The test probes 9 may be, for example, probes used for power supply testing or signal testing, and, as a result of using the placement illustrated in FIGS. 4-6, these test probes 9 can be shielded from adjacent test probes 9 as well as from external signals in the axial direction “α” and in the “β-γ” plane by the main body portions 11 of the test probes 1, 1A serving as ground probes and, furthermore, by the shielding portions 13 of the test probes 1, 1A. In particular, if the placement illustrated in FIGS. 5, 6 is used, the test probes 9 can be surrounded by the test probes 1, 1A substantially on all sides, and the test probes 9 can therefore be almost completely shielded from the outside. Although the test probes 1, 1A are configured as probes specially adapted for use as ground probes in this manner, they are not limited to use as ground probes, and they can also, of course, be employed as probes used for power supply testing or signal testing.

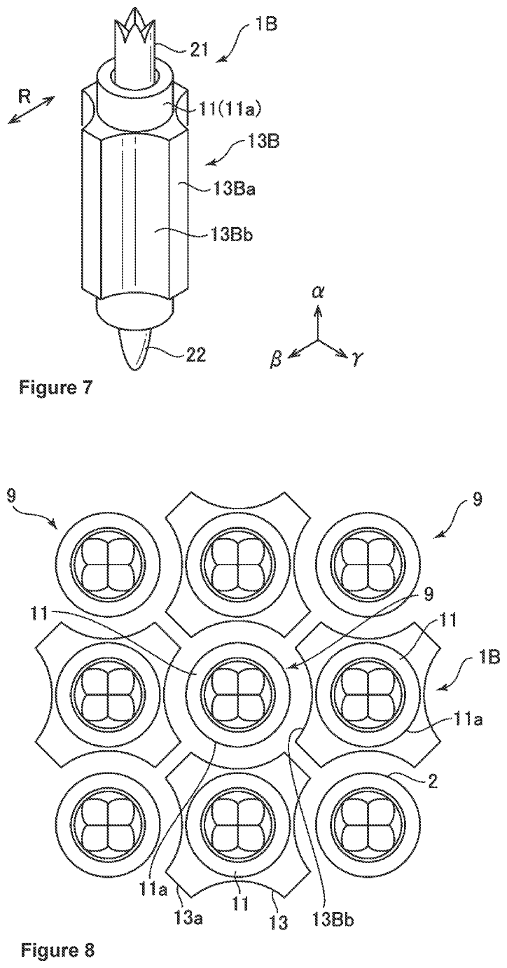

FIG. 7 illustrates a test probe 1B used in a variation obtained by modifying the shape of the shielding portions and, furthermore, FIG. 8 is a plan view similar to FIGS. 5, 6 that illustrates an example of the placement of test probes 1B in a test socket (omitted here for simplicity).

In the “β-γ” plane, the shielding portions 13B of the test probe 1B have a shape that tapers away from the peripheral surface 11a in the radial direction “R”. Adopting such a shape makes it possible to further improve shielding capability at locations closer to the test probes 1B without obstructing the placement of other test probes. The outlines 13Bb of the tapering shielding portions 13B may be curved. It is preferable to position the curved outlines 13Bb substantially concentrically with the peripheral surface 11a of the main body portions 11 of adjacent test probes 9. By adopting such positioning, the distance between test probes 1B and test probes 9 is constant, thereby making it possible to more effectively prevent noise generation.

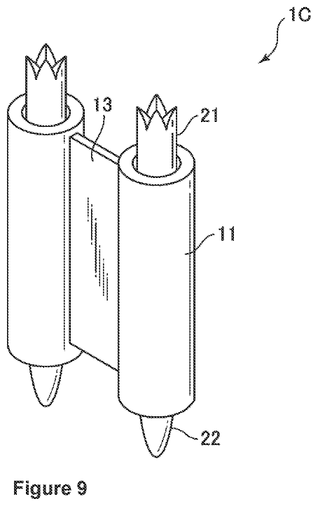

FIG. 9 is a perspective view illustrating an exemplary aspect involving test probe coupling. As shown in this drawing, adjacent test probes may be coupled using, for instance, the shielding portion 13 of the test probe 1A illustrated in FIG. 3. The number of the coupled test probes is not particularly limited, and two or more test probes may be coupled. It should be noted that the test probes 1 illustrated in FIG. 2, the test probes 1B illustrated in FIG. 7, as well as the test probes described hereinbelow, may be coupled in the same manner.

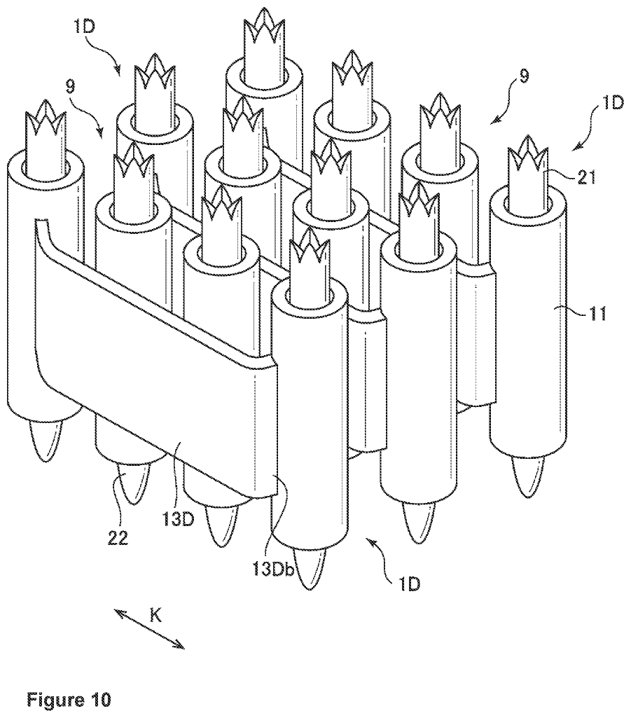

Although FIG. 9 illustrates an example of coupling test probes located in close proximity, as shown in FIG. 10, test probes 1D located at a distance may also be coupled. FIG. 10 is a perspective view similar to FIG. 4 that illustrates an example of the placement of test probes 1D in a test socket (omitted here for simplicity). One or more test probes 9 can be shielded when they are placed between a single set of test probes 1D coupled by shielding portions 13D. In such a case, in order to further increase their shielding capability, the test probes 9 placed between the test probes 1D are, if possible, preferably arranged in a linear configuration along the array direction “K” of the test probes 1D coupled by the shielding portion 13D. For this reason, the shielding portions 13D are provided with bent portions 13Db that bend in the “β-γ” plane away from the array direction “K” of the adjacent test probes 1D coupled by the shielding portion 13D. Although not specifically illustrated, the test probes 1 illustrated in FIG. 2, the test probes 1B illustrated in FIG. 7, and other test probes may be coupled in the same manner.

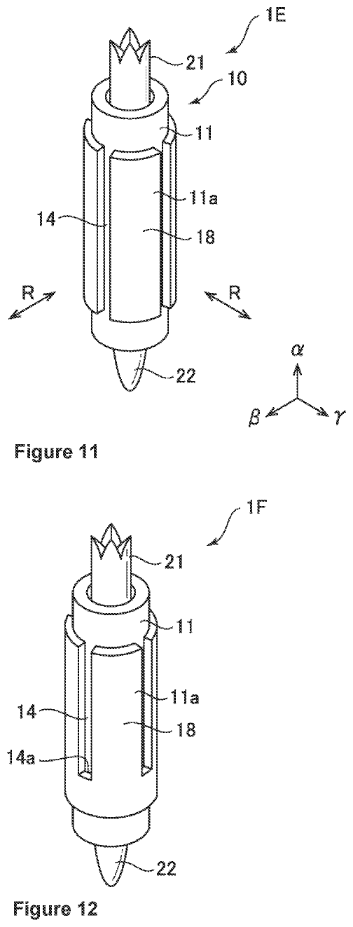

FIG. 11 shows a schematic perspective view of a test probe 1E according to a second exemplary embodiment of the present invention. The test probe 1E has an outer casing that is different from those of the test probes 1, etc., illustrated in FIG. 2, etc. More specifically, instead of the shielding portions 13B of the test probe 1, the outer casing 10 of the test probe 1E includes recessed portions 14.

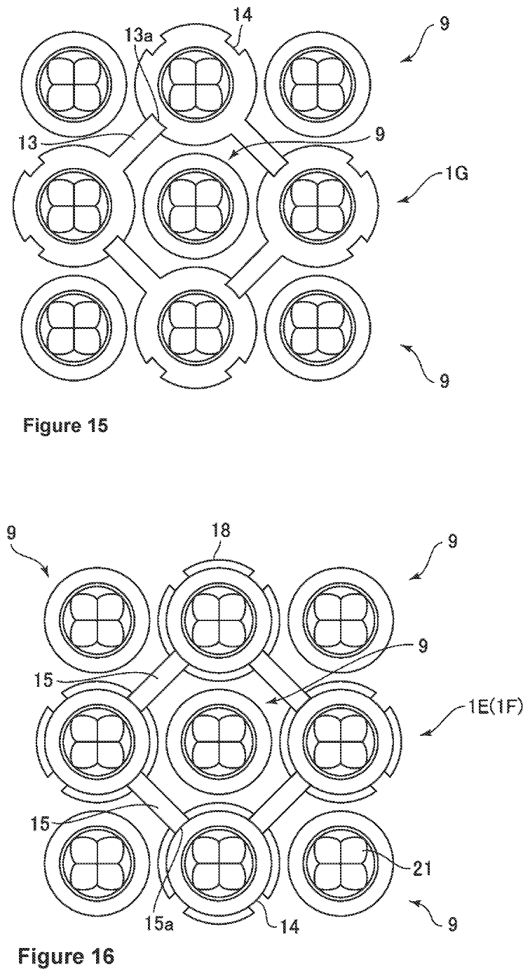

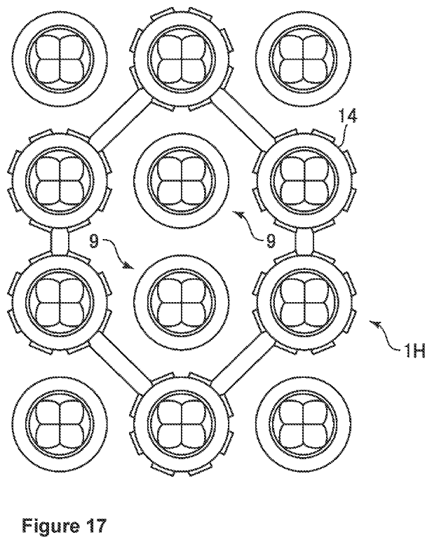

The ends 13a of the shielding portions 13 of the other test probes 1, 1A illustrated in FIGS. 1A, 2 (see FIGS. 2-6), the ends 13Ba of the shielding portions 13B of the test probes 1B illustrated in FIG. 7 (see FIGS. 7, 8), and other shielding portions, as well as the ends 15a (see FIG. 16) of the “shielding members” (designated by reference numeral “15” in the hereinafter-described FIG. 16), are installed in the recessed portions 14. As used herein, the term “shielding member” refers to a member that has a size and shape similar to those of a shielding portion, but unlike a shielding portion, is not part of a test probe and is provided separately and independently from a test probe. In this manner, the test probes 1E may be coupled to other test probes in the same manner as in the variation illustrated in FIG. 2, etc., by installing predetermined sections of the shielding portions and/or shielding members in the recessed portions 14.

The recessed portions 14 are provided as indentations in a radial direction “R” of the main body portion 11 in parts of the peripheral surface 11a of the main body portion 11. The recessed portions 14 may be formed using, for instance, an annular raised portion 18 on the main body portion 11. The recessed portions 14 are formed by indenting parts of the peripheral surface 11a of the main body portion formed by the raised portion 18 in a radial direction “R”. In this manner, forming the recessed portions 14 using the raised portion 18 makes it possible to form the recessed portions 14 without reducing the wall thickness of the main body portion 11 and, therefore, without weakening the integrity of the test probe.

In addition, each recessed portion 14 is provided over a predetermined length along the axial direction “α”. This length can be determined freely by considering the size of the apparatus and shielding effects, and, furthermore, the size, etc., of the ends of the shielding portions 13 and/or shielding members installed in the recessed portions 14.

If the recessed portions 14 are provided along the axial direction “α” throughout the entire raised portion 18, the ends of the shielding portions and/or shielding members installed in the recessed portions 14 are at risk of decoupling and falling out, in particular on the bottom side. A test probe IF, which has at least one end in the axial direction “α” of its recessed portions 14, in particular, the bottom end 14a, substantially closed in the “β-γ” plane, as shown in FIG. 12, may be used in order to stabilize their installation and prevent decoupling and falling out.

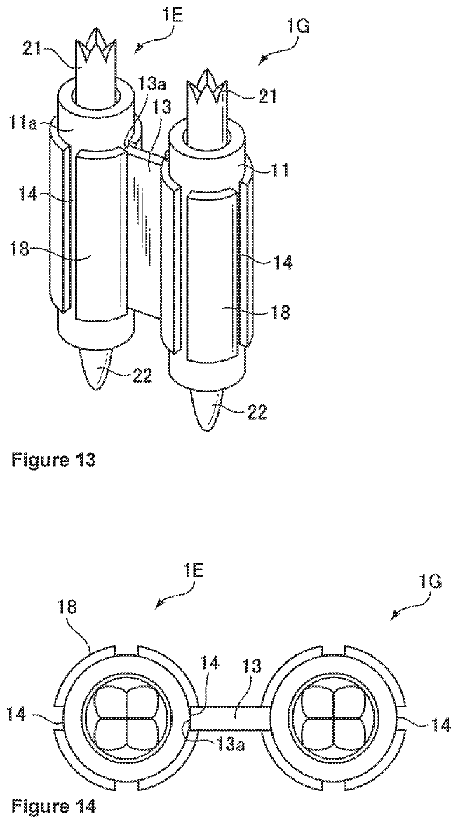

The number of the recessed portions 14 is not particularly limited. Although test probe 1E is provided with a total of four recessed portions 14, it may be provided with, for example, one portion, three portions (as in the hereinafter-described FIGS. 13-15), or eight portions (as in the hereinafter-described FIG. 17).

If a plurality of recessed portions 14 are provided, as shown in FIG. 11, in the “β-γ” plane, these recessed portions 14 may be placed in a radial configuration and in an equidistantly spaced relationship with respect to one another. However, the placement does not necessarily have to be radial or equidistantly spaced. The method of placement can be modified as appropriate depending on the mode of use.

FIGS. 13-17 illustrate various aspects of coupling involving test probes that are coupled using recessed portions 14. It should be noted that, while test probes provided with shielding members have been described in the first embodiment illustrated in FIG. 1, etc. and test probes provided with recessed portions have been described in the second embodiment illustrated in FIG. 11, etc., respectively, test probes may be provided with combination of these as shown in FIGS. 13-15.

In FIGS. 13-15, a single test probe 1G is provided with both recessed portions 14 and a shielding portion 13. FIG. 13 is a perspective view illustrating an aspect involving coupling a test probe 1G and a test probe 1E (1F) such as the one illustrated in FIG. 11 (FIG. 12), and FIG. 14 is a plan view thereof. As shown in these drawings, test probes 1G and test probes 1E (1F) can be coupled by installing the end 13a of the shielding portion 13 of test probes 1G in a recessed portion 14 of test probes 1E.

FIG. 15 illustrates another aspect involving coupling test probes 1G and test probes 1E (1F) in a plan view similar to FIG. 14. In this coupling-related aspect, test probes 1G are coupled to other test probes 1G in addition to test probes 1E (1F). Due to the fact that a test probe 1G has both recessed portions 14 and a shielding portion 13, as shown in this drawing, in addition to being able to couple to other test probes 1E (1F) using its own shielding portion 13, it may be coupled with other test probes 1G. It should be noted that although the test probes 1G illustrated in these FIGS. 13-15 have three recessed portions 14 and one shielding portion 13, of course, the total number of these recessed portions and shielding portions, and the respective numbers of the recessed portions and shielding portions are not particularly limited.

FIG. 16, which is a plan view similar to FIG. 15, achieves the same coupling-related aspect as the one in FIG. 15 using test probes 1E (1F) having only recessed portions 14. Since test probes 1E (1F) do not have shielding portions 13 like test probes 1G, in this case, test probes 1E (1F) are coupled to each other with the help of shielding members 15. Although FIG. 17 also illustrates a coupling-related aspect that makes use of test probes 1H having only recessed portions 14, in this case, a total of eight recessed portions 14 are provided in a radial configuration, which is why this coupling-related aspect is more complicated than the coupling-related aspect illustrated in FIG. 16. An advantage of the coupling-related aspect illustrated in FIG. 17 is that a total of two test probes 9 can be shielded by a total of six test probes 1H using less surface area.

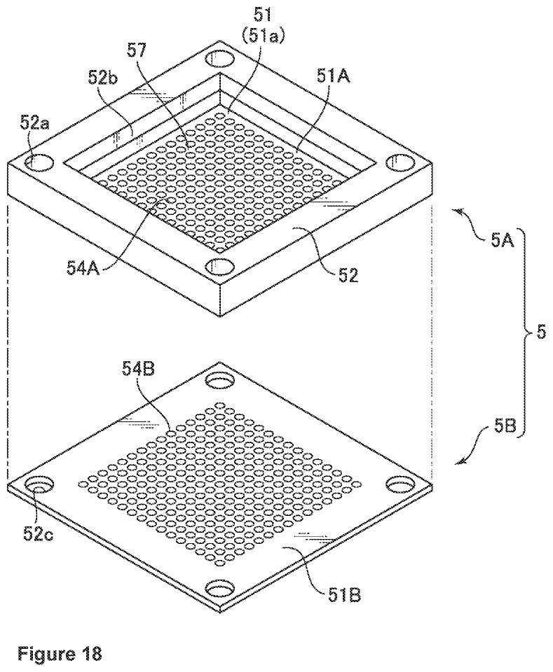

FIG. 18 shows a schematic perspective view of a test socket according to an exemplary embodiment of the present invention. The test socket 5 is made up of an upper housing 5A and a lower housing 5B, which are combined while accommodating the inventive test probes 1, etc., illustrated in FIGS. 1-17, as well as other test probes. The upper housing 5A includes a base 51 made of plastics and a frame body 52 that supports the base 51 and is provided surrounding the outer periphery of the base 51.

The test probes are arranged with the help of through-holes 54A provided in the base 51A of the upper housing 5A and through-holes 54B provided in the base 51B of the lower housing 5B in a grid-like pattern according to the placement of the through-holes 54A, 54B.

When the test probes 1, etc., are accommodated in the upper housing 5A and lower housing 5B, roughly the upper halves of the test probes are accommodated within the accommodating space of the upper housing 5A, and roughly the lower halves of the test probes are accommodated within the accommodating space of the lower housing 5B, respectively (see FIG. 19). Further, at such time, portions of the contact members 21 of the test probes, in particular, the multi-point contact portions 21a provided at the distal ends thereof (see FIG. 1, etc.), are installed so as to protrude slightly upwardly of the surface 51a of the base 51 through the through-holes 54A and, similarly, portions of the contact members 22 of the test probes 1, etc., in particular, the contact point portions 22a provided at the distal ends thereof (see FIG. 1, etc.), are installed so as to protrude slightly downwardly of the bottom surface of the lower housing 5B through the through-holes 54B.

The frame body 52 includes screw holes 52a and, in the same manner, the lower housing 5B includes screw holes 52c. The frame body 52 and lower housing 5B, along with the base 51, are screwedly secured at predetermined locations of a printed circuit board or another test apparatus (not shown) using these screw holes 52a, 52c. Once they have been secured at the predetermined locations, each contact member 21 of the test probes 1, etc., incorporated into the base 51 of the test socket 5 is electrically connected to a predetermined portion of the test apparatus.

The electronic device under test (not shown) is inserted into a recess-like installation portion 57 formed by the interior wall surfaces 52b of the frame body 52 and the surface 51a of the base 51. As a result, predetermined sections of the electronic device, for example, predetermined solder balls of the IC circuits, etc., are electrically and resiliently connected to the respective multi-point contact portions 21a of the contact members 21 arranged on the surface 51a of the base 51. A plurality of electronic devices under test may be alternately inserted into and extracted from the test socket 5. The electric power required for electronic device testing can be supplied, for example, from the test apparatus. The electric current from the test apparatus is supplied to the electronic device through the electrical connection between the test apparatus and the contact point portions 22a of the contact members 22.

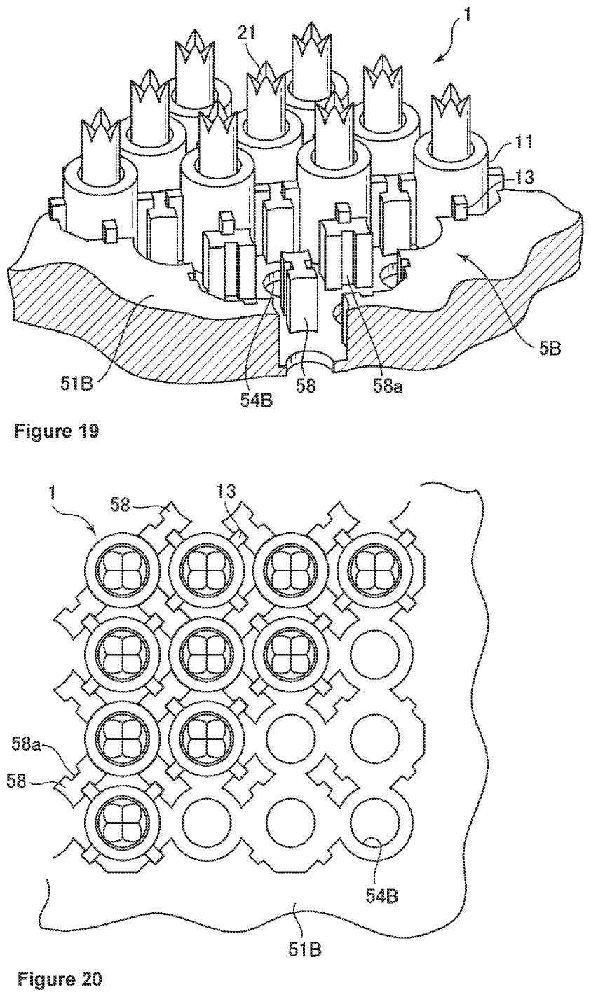

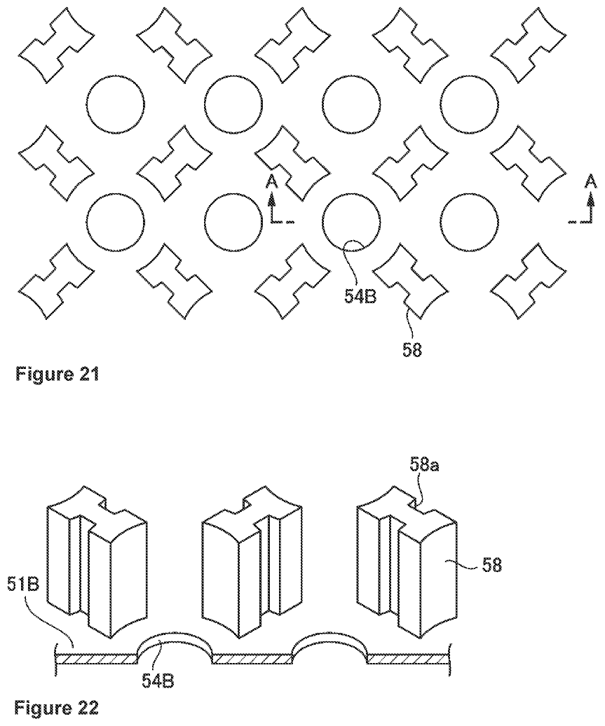

FIG. 19 is a perspective partial cut-away view that illustrates an arrangement of test probes 1 accommodated in the lower housing 5B, and, furthermore, FIG. 20 shows a schematic plan view thereof. In the lower housing 5B, in addition to the through-holes 54B in which the main body portions 11 of the outer casings of the test probes 1 are accommodated, retaining members 58, which retain shielding portions 13 or shielding members 15, are provided around the periphery thereof. Furthermore, the plan view shown in FIG. 21 illustrates the placement of the retaining members 58 and the through-holes 54B prior to the installation of the test probes 1, and FIG. 22 shows a perspective cross-sectional view taken along line A—A in FIG. 21. As best shown in these drawings, the retaining members 58 have a substantially H-like configuration when seen in plan view, and providing the retaining members 58, which are adapted to permit receiving and retaining the vicinity of the ends 13b, 15b of the shielding portions 13 or shielding members 15 of the test probes in recesses 58a provided at opposed locations thereof, is believed to make it possible to install the test probes 1, etc., in the test socket 5 in a reliable and stable manner. In addition, as a result of providing the retaining members 58 at locations corresponding to the through-holes 54B, the freedom of design is increased to allow any possible placement of the test probes.

Many modifications or other embodiments of the present invention will come to mind to one skilled in the art to which the invention pertains having the benefit of the teachings presented in the foregoing description, and it will be apparent to those skilled in the art that variations and modifications of the present invention may be made without departing from the scope or spirit of the invention. Therefore, it is to be understood that the invention is not to be limited to the specific embodiments disclosed and that modifications and other embodiments are intended to be included within the scope of the appended claims.

### DESCRIPTION OF THE REFERENCE NUMERALS

1 Test probe having shielding capability
5 Test socket
9 Test probe
10 Outer casing
11 Main body portion
11a Peripheral surface
13 Shielding portion
13a End
14 Recessed portion
15 Shielding member

1. A test probe comprising a hollow outer casing made of an electrically conductive material, a resilient member installed within the outer casing in a manner permitting contraction and expansion in an axial direction, and contact members installed within the outer casing in a state of being constantly biased by the resilient member while partially protruding outside of the outer casing, wherein
the probe is configured such that
the outer casing includes
a cylindrical main body portion extending in the axial direction and
a shielding portion provided along the axial direction as a protrusion in a radial direction of the main body portion in part of the peripheral surface of the main body portion,
or alternatively, such that
the outer casing includes
a cylindrical main body portion extending in the axial direction and
a recessed portion provided along the axial direction as an indentation in a radial direction of the main body portion in part of the peripheral surface of the main body portion, and an end of the shielding portion and/or an end of a shielding member of another test probe to be coupled can be installed in the recessed portion.

2. The test probe according to claim 1, wherein a plurality of the shielding portions or the shielding members are installed in a radial configuration in a plane intersecting the axial direction.

3. The test probe according to claim 1, wherein the shielding portions or the shielding members have a linear shape extending in a substantially even width in a plane intersecting the axial direction.

4. The test probe according to claim 1, wherein the shielding portions or the shielding members have a shape that tapers away from the peripheral surface in the radial direction in a plane intersecting the axial direction.

5. The test probe according to claim 4, wherein the outline of at least part of the shielding portions or the shielding members is curved in a plane intersecting the axial direction.

6. The test probe according to claim 1, wherein a plurality of test probes are coupled by the shielding portions or the shielding members.

7. The test probe according to claim 6, wherein the shielding portions or the shielding members have bent portions that bend away from the array direction of adjacent test probes coupled by the shielding portions or the shielding members in a plane intersecting the axial direction.

8. The test probe according to claim 1, wherein the recessed portions are formed using an annular raised portion on the main body portion.

9. The test probe according to claim 1, wherein at least one end of the recessed portions in the axial direction is substantially closed in a plane intersecting the axial direction.

10. A test socket for use with the test probe according to any of claims 1 to 9.

11. The test socket according to claim 10, wherein retaining members retaining the shielding portions or the shielding members are provided around the periphery of openings in a support in which the main body portions are accommodated.

12. The test socket according to claim 10, wherein the curved outlines of the shielding portions or the shielding members of the test probe according to claim 5 are positioned substantially concentrically with the peripheral surfaces of the main body portions of adjacent test probes.
